(19) United States
(12) Patent Application Publication
(10) Pub. No.: US 2025/0364349 A1
(43) Pub. Date: Nov. 27, 2025

(54) DUMMY FEATURES FOR DISSIPATING HEAT IN PACKAGES INCLUDING ADVANCED SEMICONDUCTOR CHIPS

(71) Applicant: Applied Materials, Inc., Santa Clara, CA (US)

(72) Inventors: An JINHO, Santa Clara, CA (US); Guan Huei SEE, Singapore (SG); Chang Bum YONG, Singapore (SG)

(21) Appl. No.: 18/672,951

(22) Filed: May 23, 2024

(51) Int. Cl. H01L 23/36; H01L 21/768; H01L 23/00; H01L 23/48; H01L 25/065

(52) U.S. Cl. CPC H01L 23/36; H01L 21/7684; H01L 21/76846; H01L 21/76898; H01L 23/481; H01L 25/0652; H01L 24/08; H01L 2224/08145

(57) ABSTRACT

Embodiments of the disclosure include a semiconductor die comprising: a substrate having a frontside opposing a backside; a device layer disposed over the frontside of the substrate; interconnect layers formed over the device layer; and at least one dummy feature. The at least one dummy feature extending from the backside of the substrate through a portion of the substrate, wherein the at least one dummy feature comprises one or more metal layers. The at least one dummy feature being electrically isolated from the device layer and the interconnect layers by a portion of the substrate.

### BACKGROUND

### Field

Embodiments of the present invention generally relate to a semiconductor device and a method of forming a semiconductor device.

### Description of the Related Art

As semiconductor technology transitions to forming higher density of circuits and electronic components, three dimensional (3D) stacked devices are being used in lieu of 2D device architectures. 3D stacked devices are able to achieve a higher device density by bonding two or more layers of semiconductor dies into a stacked architecture. 3D stacked devices can provide a higher circuit density and can improve performance by shortening interconnect distances between circuit elements formed in the stacked semiconductor dies (chips).

However, the densely packed devices in 3D stacked devices generate an increased amount of heat and include hotspots. Typically to dissipate away the additional heat and prevent hotspots heat management such as a thermal interface material or micro-cooling is performed on the outside of the device package.

Therefore, there is a need in the art for thermal management of 3D stacked semiconductor device to directly dissipate from the semiconductor chips.

### SUMMARY

Embodiments of the disclosure include a semiconductor die comprising: a substrate having a frontside opposing a backside; a device layer disposed over the frontside of the substrate; interconnect layers formed over the device layer; and at least one dummy feature. The at least one dummy feature extending from the backside of the substrate through a portion of the substrate, wherein the at least one dummy feature comprises one or more metal layers. The at least one dummy feature being electrically isolated from the device layer and the interconnect layers by a portion of the substrate.

According to one or more embodiments, a semiconductor die includes a substrate having a frontside opposing a backside, a device layer disposed over the frontside of the substrate, interconnect layers formed over the device layer, and at least one dummy feature, the at least one dummy feature extending from the backside of the substrate through a portion of the substrate, wherein the dummy feature comprises one or more metal layers.

According to one or more embodiments, a method includes depositing a photoresist layer on a backside of a substrate, the substrate comprising a device layer disposed on a frontside of the substrate, and interconnect layers disposed over the device layer, patterning the photoresist layer to form first patterned features that expose portions of the backside of the substrate, the first patterned features having a first critical dimension, etching the portions of the backside of the substrate exposed by the first patterned features using a first etching process to form first features, the first features extending from the backside of the substrate through a portion of the substrate, and filling the first features with a metal to form dummy features.

According to one or more embodiments, stacked semiconductor assembly includes a second level of semiconductor dies disposed above a first level of semiconductor dies, each of the semiconductor dies including a substrate having a frontside opposing a backside, a device layer disposed over the frontside of the substrate, interconnect layers formed over the device layer, the interconnect layers having interconnect features formed therein, at least one dummy feature, the at least one dummy feature extending from the backside of the substrate through a portion of the substrate, wherein the dummy feature comprises a metal, and at least one working TSV extending from the backside of the substrate to a corresponding interconnect feature, wherein each of the at least one working TSV of each of the semiconductor dies of second level of semiconductor dies is aligned with a corresponding working TSV of the at least one working TSV of each of the semiconductor dies of first level of semiconductor dies.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a method for forming at least one dummy feature through a semiconductor die according to one or more embodiments.

FIGS. 2A-2G each illustrate a cross-sectional view of a semiconductor die during the formation of at least one dummy feature according to one or more embodiments.

FIG. 3 illustrates a method 300 for forming at least one dummy feature through a semiconductor die according to one or more embodiments.

FIGS. 4A-4G each illustrate a cross-sectional view of a semiconductor die during formation of at least one dummy feature according to one or more embodiments.

FIG. 5 illustrates a method 500 for forming at least one dummy feature through a semiconductor die according to one or more embodiments.

FIGS. 6A-6G each illustrate a cross-sectional view of a semiconductor die during the formation of at least one dummy feature according to one or more embodiments.

FIG. 7 illustrates a method 700 for a semiconductor device assembly including at least one TSV using die-to-wafer (D2W) bonding according to one or more embodiments.

FIGS. 8A-8D illustrate a cross-sectional view of a semiconductor device during the formation a semiconductor device assembly including at least one TSV using die-to-wafer (D2W) bonding according to one or more embodiments.

FIG. 9 illustrates a method 900 for a semiconductor device assembly including at least one TSV using wafer-to-wafer (W2W) bonding according to one or more embodiments.

FIGS. 10A-10C each illustrate a cross-sectional view of a semiconductor device during the formation a semiconductor device assembly including at least one TSV using wafer-to-wafer (W2W) bonding according to one or more embodiments.

FIG. 11 illustrates a cross-sectional view of a stacked semiconductor assembly including at least one dummy feature according to one or more embodiments

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein relate to thermal management of semiconductor chips or die disposed within a semiconductor device package. In particular embodiments herein relate to a semiconductor device and method of forming a semiconductor that includes semiconductor die that can directly dissipate or “wick away” heat from portions of the semiconductor device package. Stated otherwise, semiconductor dies include dummy features formed through a surface (e.g., backside) of the semiconductor substrate that directly dissipate the heat generated by one or more stacked die without taking up space that could otherwise be used by electrical devices and/or conductive features formed on the frontside of each semiconductor substrate. The dummy features can include one or more metal layers and are electrically isolated from the electrical devices and/or conductive features formed in the semiconductor dies by a portion of the substrate.

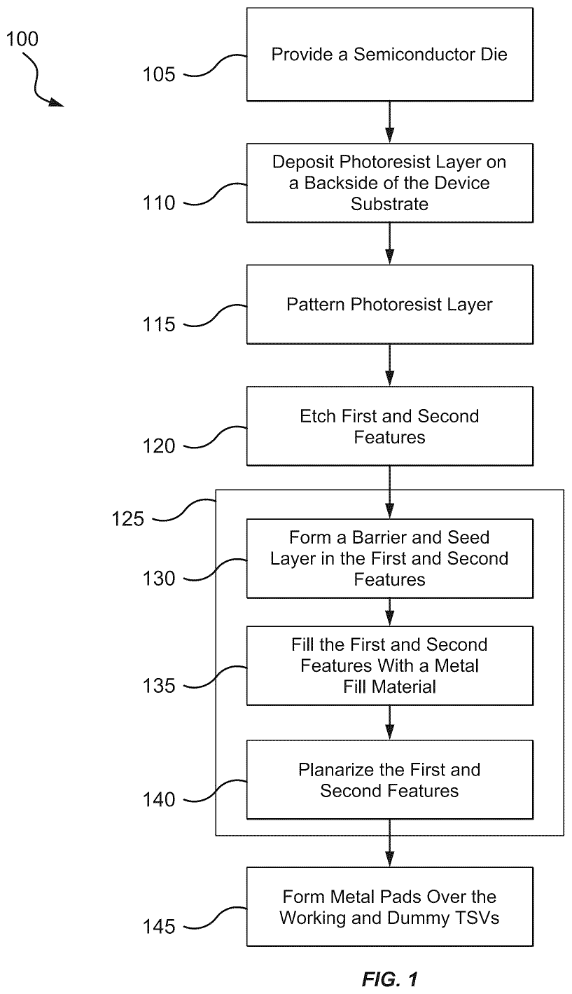

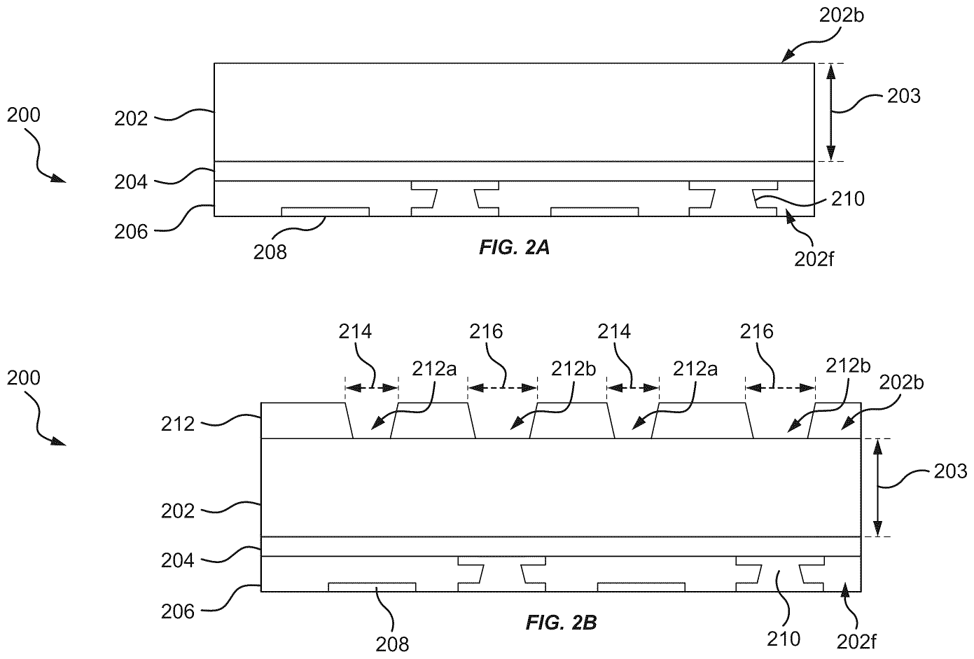

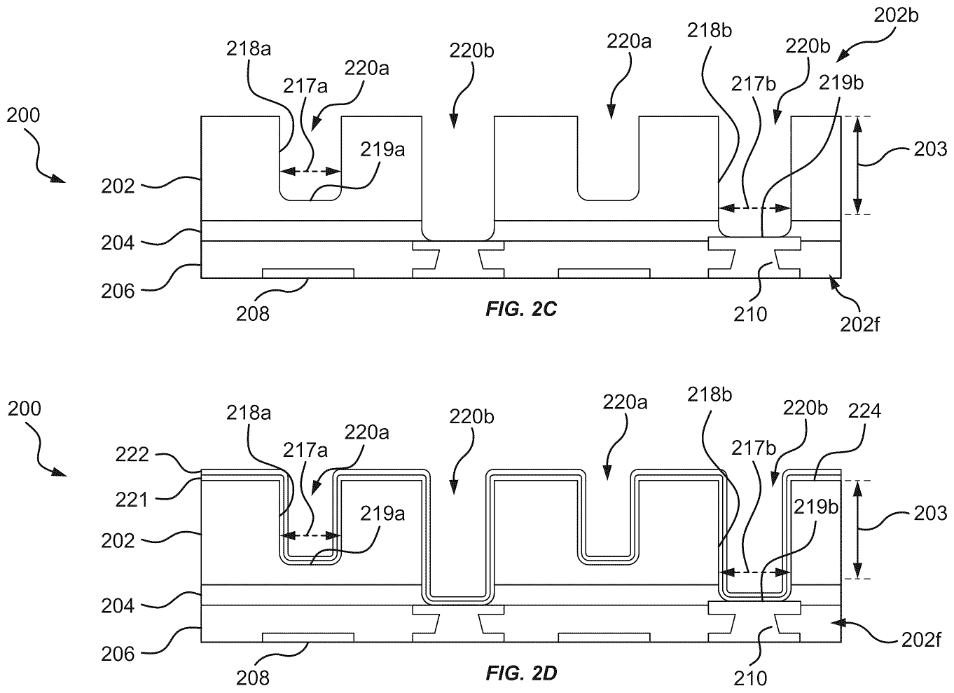

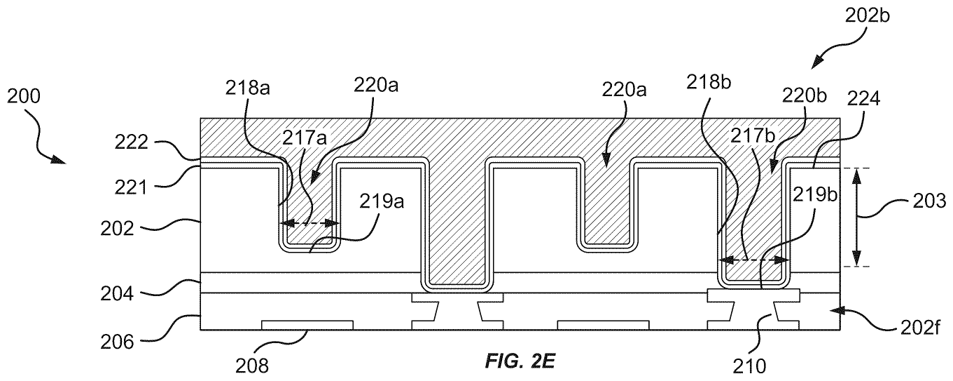

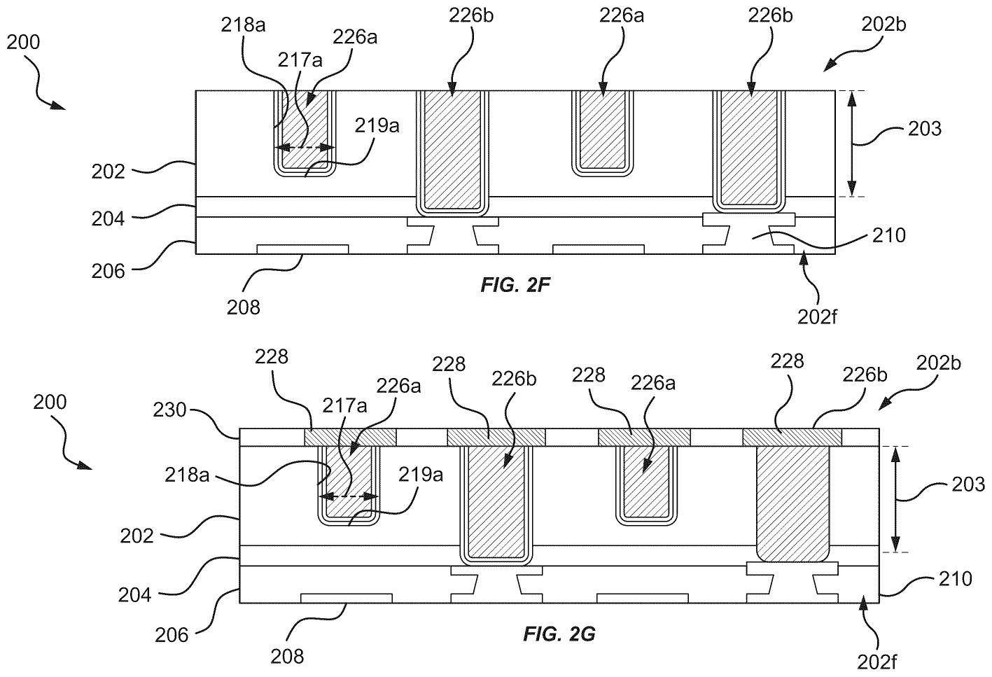

FIG. 1 illustrates a method 100 for forming at least one dummy feature within a semiconductor die according to one or more embodiments. FIGS. 2A-2G illustrate a cross-sectional view of a semiconductor die during formation of at least one dummy feature according to one or more embodiments.

At operation 105 and as illustrated in FIG. 2A, a semiconductor die 200 is provided. The semiconductor die 200 includes a substrate 202, a device layer 204 formed at the contact level, and interconnect layers 206. The device layer 204 and the interconnect layers 206 may be formed on a frontside 202f (i.e. the device side) of the substrate 202. The substrate 202 may be made from a material including, but not limited to silicon, gallium arsenide, gallium antimonide, and or other Group III-V materials either alone or in combination with silicon or silicon dioxide or other insulating materials. In some embodiments, the substrate 202 has a substrate thickness 203 extending from the frontside 202f to the backside 202b.

The device layer 204 may include dielectric, metal and doped silicon regions formed on a frontside 202f of the substrate 202. The interconnect layers 206 may be formed over the device layer 204. The interconnect layers 206 may include a combination of dielectric and metal layers. The interconnect layers 206 may also include conductive features 210, such as contacts, or interconnects that are formed through the interconnect layer 206. The conductive features 210 may include features that are etched into the interconnect layers 206 and are filled with a conductive material, such as copper. Metal pads 208 may be disposed over and in contact with the interconnect layers 206. The metal pads 208 may be formed over the conductive features 210 and/or portions of the interconnect layers 206 that do not include the conductive features 210. The metal pads 208 may comprise a conductive material, such as copper. The metal pads 208 may or may not comprise the same conductive material as the conductive features 210.

At operations 110-115, and as illustrated in FIG. 2B, a photoresist layer 212 is deposited and then patterned. The photoresist layer 212 is deposited on a backside 202b of the substrate 202. In some embodiments, the photoresist layer 212 may include, but is not limited to, one or more of an organic photoresist, such as a chemically amplified resist (CAR) or a metal oxide photoresist. In one or more embodiments, patterning the photoresist layer 212 can be done by any suitable lithography process. For example, patterning the photoresist layer 212 includes exposing the photoresist layer 212 to a patterned EUV radiation source and a developer. The developer can remove a portion of the photoresist layer 212 forming patterned features 212a and patterned features 212b that expose portions of the substrate 202. In some embodiments, the photoresist layer 212 is a negative tone photoresist and the developer removes portions of the photoresist not exposed to the radiation source. In some embodiments, the photoresist layer 212 is a positive tone photoresist and the developer removes portions of the photoresist that have been exposed to the radiation source. The patterned features 212a have a critical dimension 214 (i.e., a width). The patterned features 212b have a critical dimension 216. The critical dimension 214 may be from about 0.1 μm to about 6 μm. The critical dimension 216 may be from about 0.1 μm to about 6 μm. The critical dimension 214 is smaller than the critical dimension 216. The patterned photoresist layer 212 is configured to act a photomask for etching features into the backside 202b of the substrate 202. The patterned features 212a are positioned over the metal pads 208 formed over the interconnect layers 206 that are not positioned over the conductive features 210. The patterned features 212b are positioned over (aligned with) the conductive features 210. As will be described in more detail below, the patterned features 212a are sized and positioned to expose portions of the backside 202b of the substrate 202 in which dummy features are to be formed. The patterned features 212b are positioned and sized to expose portions of the backside 202b of the substrate 202 in which working through-silicon-vias (TSVs) are to be formed. Stated otherwise, the eventually formed dummy features are configured to dissipate the heat from the electronic device while the eventually formed working TSVs are configured to couple with the conductive features 210 and form interconnects. In another example, if working TSVs are not required, the photoresist layer 212 is only patterned with the patterned features 212a.

At operation 120, as illustrated in FIG. 2C, features 220a and features 220b are etched into the portions of the substrate 202 exposed by the photoresist layer 212. As noted above, the features 220a are etched into the portions of the backside 202b of the substrate 202 exposed by the patterned features 212a. The features 220b are etched into the portions of the backside 202b of the substrate 202 exposed by the patterned features 212b. The features 220a each have a sidewall surface 218a, a bottom surface 219a, and a width (critical dimension) 217a. The features 220b each have sidewall surfaces 218b, a bottom surface 219b, and a width (critical dimension) 217b. Due to the differences in sizes of the critical dimension 214 and the critical dimension 216, the features 220a have a smaller width 217a than the width 217b of the features 220b. Both features 220a, 220b may be any suitable feature for forming a TSV, including, but not limited to, a trench.

The features 220a are etched through a portion of the backside 202b of the substrate 202 without reaching the frontside 202f of the substrate 202. Stated otherwise, the features 220a are etched through a portion of the substrate thickness 203. The substrate thickness may be from about 2 μm to about 30 μm. The features 220b are etched through the entire substrate 202 and the device layer 204 (and reach the corresponding conductive features 210). After the features 220a and the features 220b are etched, the photoresist layer 212 is removed. In one example, the features 220a and the features 220b may be formed in a single etch process. In another example, the features 220a and the features 220b may formed using separate etch processes. For example, the features 220a may be formed using a first etch process and the features 220b may be formed using a second etch process (or vice versa). In another embodiment, if working TSVs are not required, only the features 220a are formed. The features 220a and the features 220b may be etched using any suitable etching process, such as atomic layer etching (ALE), reactive ion etching (RIE), wet etching, anisotropic etching, or the like.

At operation 125, the features 220a and the features 220b are filled, forming dummy features 226a and working TSVs 226b (FIGS. 2D-2F). Operation 125 may include operations 130-140. In another example, if working TSVs are not required the features 220a are only formed and operation 125 is only performed on the features 220a.

At operation 130, as illustrated in FIG. 2D, a barrier layer 221 and a seed layer 222 are deposited in the features 220a and the features 220b. The barrier layer 221 is deposited prior to the seed layer 222. The barrier layer 221 is deposited over the field region 224 (i.e., the unetched regions) of the backside 202b of the substrate 202 and line the sidewall surfaces 218a and bottom surface 219a of the features 220a and the sidewall surfaces 218b and bottom surface 219b of the features 220b. The barrier layer 221 may be deposited using any suitable deposition process such as atomic layer deposition (ALD), physical vapor deposition (PVD), plasma enhanced chemical vapor deposition (PECVD), chemical vapor deposition (CVD), or the like. The barrier layer 221 may comprise a metal such as tantalum (Ta), tantalum nitride (TaN), titanium (Ti), titanium nitride (TiN), or the like.

The seed layer 222 may be deposited over the barrier layer 221 within the features 220a and the features 220b, and on the field region 224 of the backside 202b of the substrate 202. The seed layer 222 may comprise any suitable metal such as copper. In some embodiments, the seed layer 222 may include copper and a dopant such as, lanthanum, titanium, tungsten, zirconium, antimony, calcium, or the like. The seed layer 222 may be deposited using any suitable deposition process such as atomic layer deposition (ALD), physical vapor deposition (PVD), plasma enhanced chemical vapor deposition (PECVD), chemical vapor deposition (CVD), or the like.

At operation 135, as illustrated in FIG. 2E a metal fill material 225 is formed over the backside 202b of the substrate 202. The metal fill material 225 fills the remaining exposed portions of the features 220a and the features 220b and covers the field region 224 of the substrate 202. Stated differently, the metal fill material 225 covers the seed layer 222. The metal fill material 225 may comprise any suitable conductive material, such as copper, for example. The metal fill material 225 may be formed using any suitable method such as electrochemical plating (ECP).

At operation 140, as illustrated in FIG. 2F, the features 220a and the features 220b are planarized using a chemical mechanical polishing (CMP) process. The CMP process removes the metal fill material 225, the seed layer 222, and the barrier layer 221 from the field region 224 of the substrate 202, forming dummy features 226a in the features 220a and working TSVs 226b in the features 220b.

At operation 145, as illustrated in FIG. 2G metal pads 228 are formed over the dummy features 226a and the working TSVs 226b. The metal pads 228 may comprise the same material as the metal pads 208, such as copper. The metal pads 228 may be formed by depositing a patterned mask layer 230 on the backside 202b that exposes both the dummy features 226a and the working TSVs 226b. The patterned mask layer 230 may be a patterned photoresist layer, a patterned oxide layer (i.e., silicon oxide), or any other suitable patterned mask layer 230. The metal pads 228 are formed by depositing a conductive material, over the dummy features 226a and the working TSVs 226b (i.e., the exposed portions of the backside 202b of the substrate 202). The patterned mask layer 230 may be removed after forming the metal pads 228. In one or more examples, if only dummy features 226a are formed, operation 145 is optional.

Advantageously, because the dummy features 226a (and the features 220a) do not extend through the substrate 202 they can dissipate heat conducted through the substrate 202. On the other hand, because the working TSVs 226b extend to the conductive features 210, the working TSVs 226b act as signal, power, or any other type of TSVs. Also, because the dummy features 226a are formed on the backside 202b of the substrate 202, the dummy features 226a are able to dissipate heat without taking up space that could otherwise be used by electrical devices and/or conductive features formed on the frontside 202a, such as transistors. Furthermore, the dummy features 226a being formed on the backside 202b do not impact the placement of electrical devices and/or conductive features formed on the frontside 202a and allows freedom to place dummy features 226a where needed to dissipate heat. The dummy features 226a are positioned a distance away from and are electrically isolated from the devices formed in device layer 204 by portions of the substrate material.

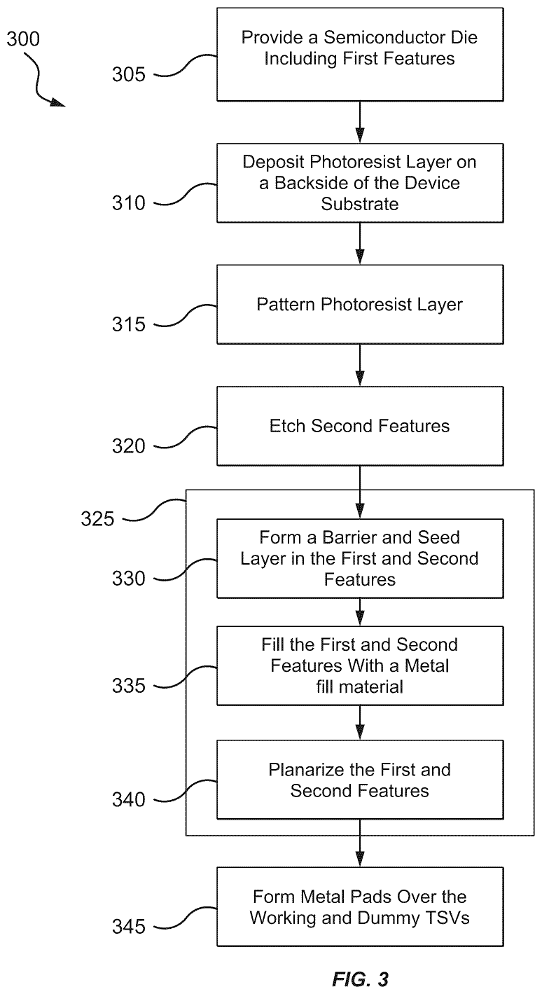

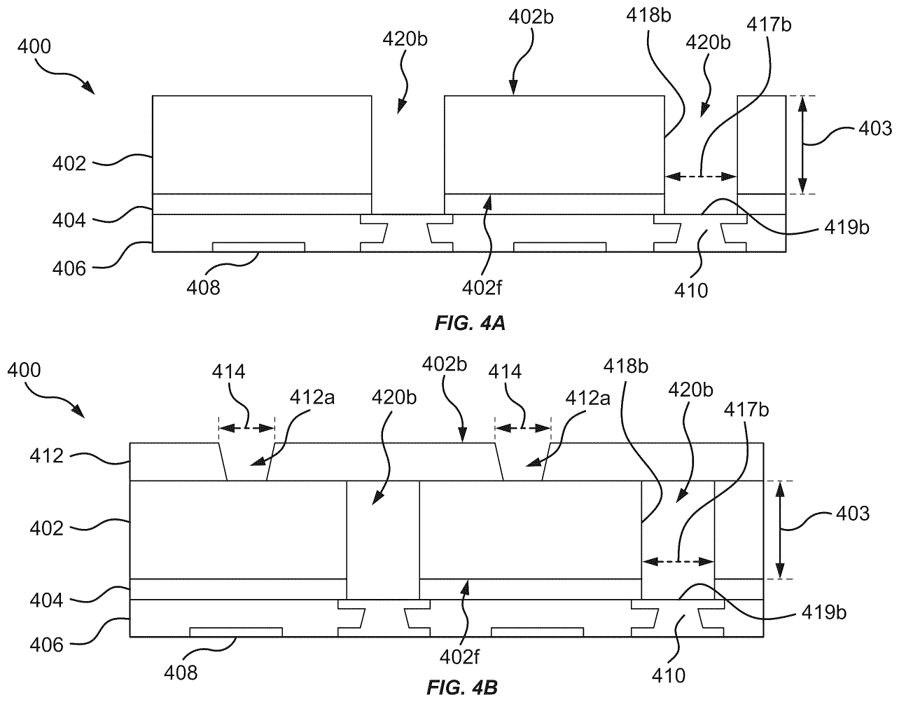

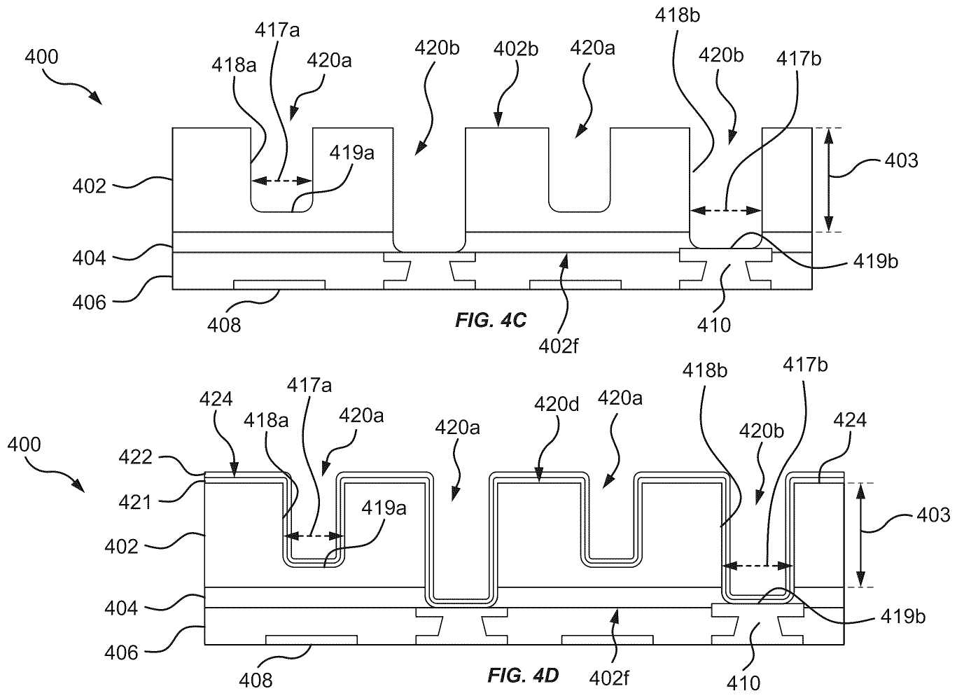

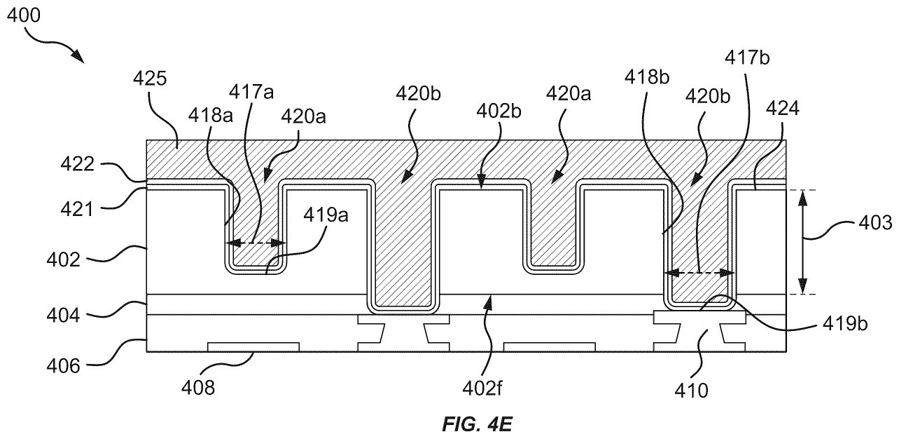

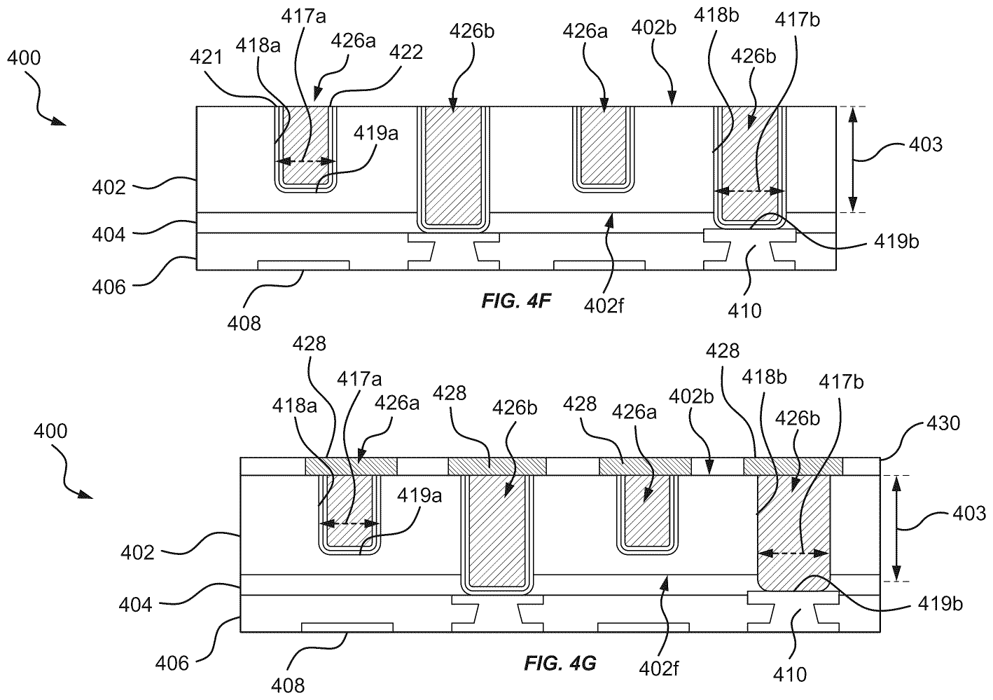

FIG. 3 illustrates a method 300 for forming at least one dummy feature through a semiconductor die according to one or more embodiments. FIGS. 4A-4G illustrate a cross-sectional view of a semiconductor die during formation of at least one dummy feature according to one or more embodiments.

At operation 305 and as illustrated in FIG. 4A, a semiconductor die 400 is provided. The semiconductor die 400 includes a substrate 402, a device layer 404 formed at the contact level, and interconnect layers 406. The device layer 404 and the interconnect layers may be formed on a frontside 402f of the substrate 402. The substrate 402 may comprise the same material as substrate 202 of FIGS. 2A-2G. In some embodiments, the substrate 202 has a substrate thickness 403 extending from the frontside 402f to a backside 402b of the substrate 402. The interconnect layers 406 may be formed over the device layer 404. The interconnect layers 406 may include a combination of dielectric and metal layers. The interconnect layer 406 may also include conductive features 410, such as contacts, or interconnects that are formed through the interconnect layer 406. Metal pads 408 may be disposed over the interconnect layers 406. The metal pads 408 may comprise a conductive material such as copper. The metal pads 408 may be formed from a same conductive material or a different conductive material than the conductive features 410. The metal pads 408 may be formed of the same material and in the same manner as the metal pads 208 of FIGS. 2A-2E. In one or more embodiments, features 420b are etched into the substrate 402. The features 420b are etched through the device layer 404 and extend from the backside 402b of the substrate 402 to (and are aligned with) corresponding conductive features 410. In one or more embodiments, the features 420b are etched after formation of the conductive features 420b. The features 420b each have sidewall surfaces 418b, a bottom surface 419b, and a width (critical dimension) 417b. The features 420b may be any feature suitable for forming a working TSV, including, but not limited to, a trench.

At operations 310-315, and as illustrated in FIG. 4B, a photoresist layer 412 is deposited and then patterned. The photoresist layer 412 is deposited on a backside 202b of the substrate 202. The photoresist layer 412 may comprise the same material and be formed in the same manner as the photoresist layer 212 in FIG. 2B. In some embodiments, because the features 420b (the structures for working TSVs) are already etched, the photoresist layer 412 includes patterned features 412a having a critical dimension of 414. Because the photoresist layer 412 will be used as an etch mask for forming features that will house dummy features and the features 420b will house working TSVs, the critical dimension 414 is smaller than the critical dimension (i.e., the width 417b) of the features 420b. The patterned features 412a are positioned over the metal pads 408 formed that are not disposed over the conductive features 410

At operation 320, and illustrated in FIG. 4C, features 420a are etched into the portions of the substrate 402 exposed by the photoresist layer 412. As noted above, the features 420a are etched into the portions of the substrate 402 exposed on the backside 402b by the patterned features 412a. The features 420a each have sidewall surfaces 418a, a bottom surface 419a, and a width (critical dimension) 417a. The width 417a is smaller than the width 417b. The features 420a, may be any suitable feature for forming a TSV, including, but not limited to, a trench.

The features 420a are etched through a portion of the backside 402b of the substrate 402 without reaching the frontside 402f of the substrate 402. After the features 420a are etched, the layer of photoresist layer 412 is removed. The features 420a may be etched using any suitable etching process, such as atomic layer etching (ALE), reactive ion etching (RIE), wet etching, anisotropic etching, or the like.

At operation 325, the features 420a and the features 420b are filled, forming dummy features 426a and working TSVs 426b (FIGS. 4D-4F). Operation 325 may include operations 330-340.

At operation 330, as illustrated in FIG. 4D, a barrier layer 421 and a seed layer 422 are deposited in the features 420a and the features 420b. The barrier layer 421 and the seed layer 422 may be deposited in the same manner and comprise the same material as the barrier layer 221 and the seed layer 222 of FIG. 2D, respectively. The barrier layer 421 is deposited prior to the seed layer 422. The barrier layer 421 is deposited over the field region 424 (i.e., the unetched regions) of the backside 402b of the substrate 402 and line the sidewall surfaces 418a and bottom surface 419a of the features 420a and the sidewall surfaces 418b and bottom surface 419b of the features 420b. The seed layer 422 may be deposited over the barrier layer 421 within the features 420a and the features 420b, and on the field region 424 of the backside 402b of the substrate 402.

At operation 335, as illustrated in FIG. 4E a metal fill material 425 is formed over the substrate 402. The metal fill material 425 fills the remaining exposed portions of the features 420a and the features 420b, and covers the field region 424 of the substrate 402. Stated differently, the metal fill material 425 covers the seed layer 422. The metal fill material 425 may be formed in the same manner and comprise the same material as the metal fill material 225 of FIG. 2E.

At operation 340, as illustrated in FIG. 4F, the features 420a and the features 420b are planarized using a chemical mechanical polishing (CMP) process. The CMP process removes the metal fill material 425, the seed layer 422, and the barrier layer 421 from the field region 424 of the substrate 402, forming dummy features 426a in the features 420a and working TSVs in the features 420b.

At operation 345, as illustrated in FIG. 4G metal pads 428 are formed over the dummy features 426a and the working TSVs 426b. The metal pads 428 may comprise the same material as the metal fill material 425, such as copper. The metal pads 428 may be formed using a patterned masking layer 430 in the same manner and comprise the same materials as the metal pads 228 (and the patterned masking layer 230) of FIG. 2G. In one or more embodiments, if only dummy features 426a are formed, operation 345 is optional.

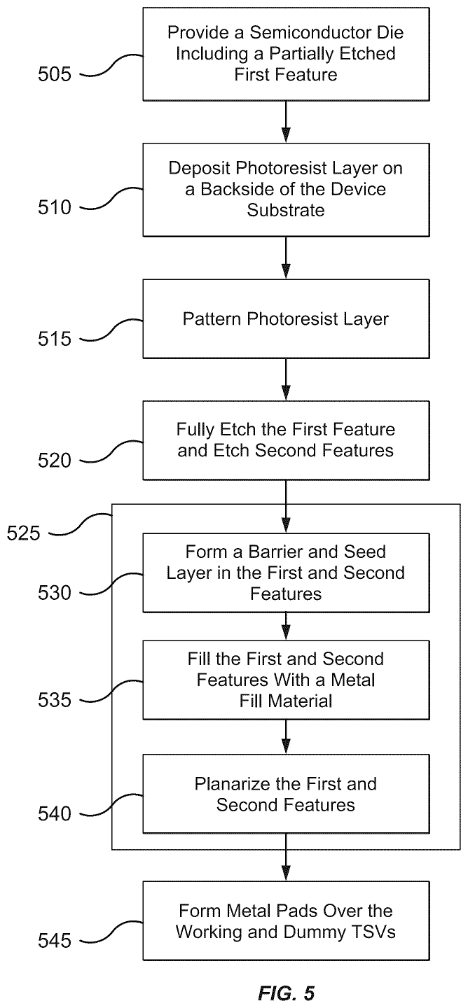

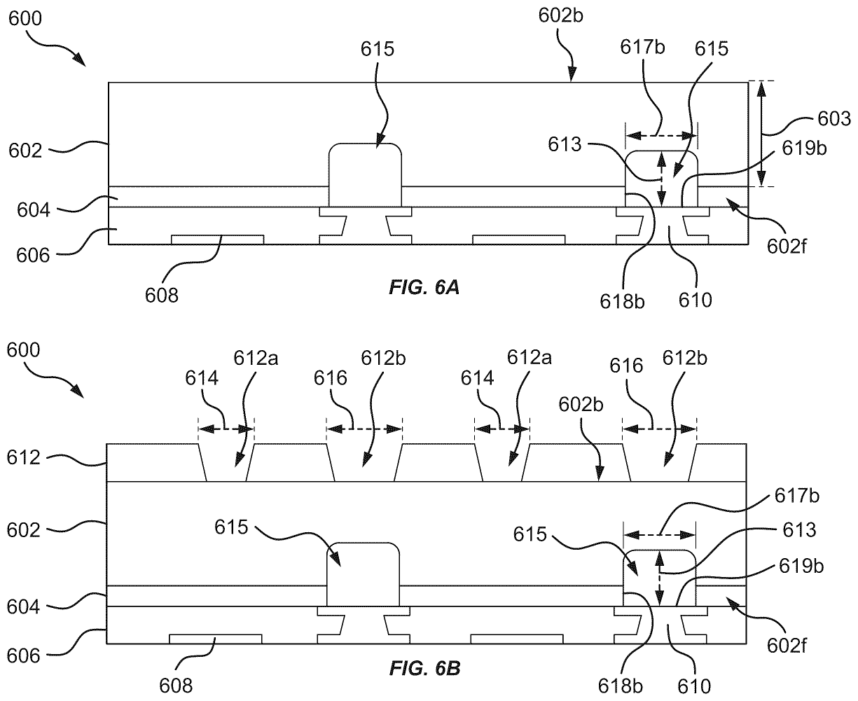

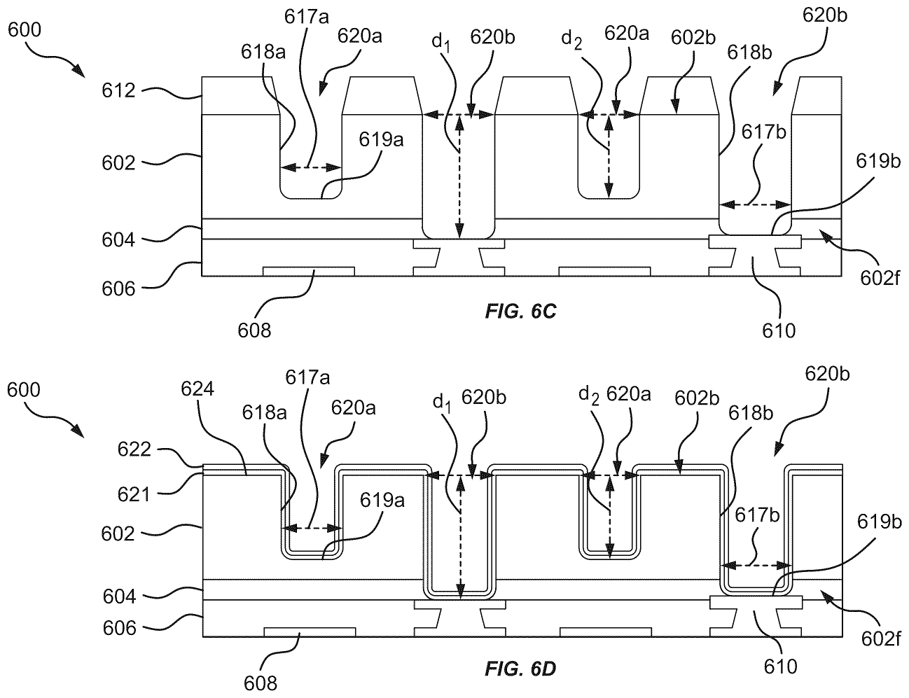

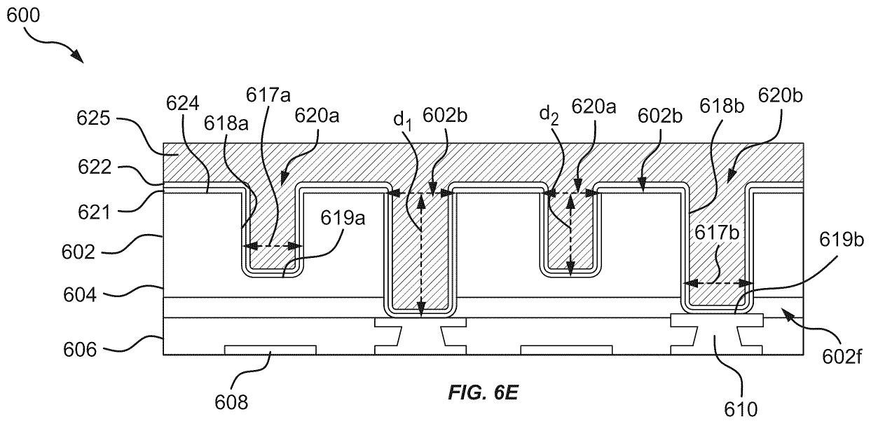

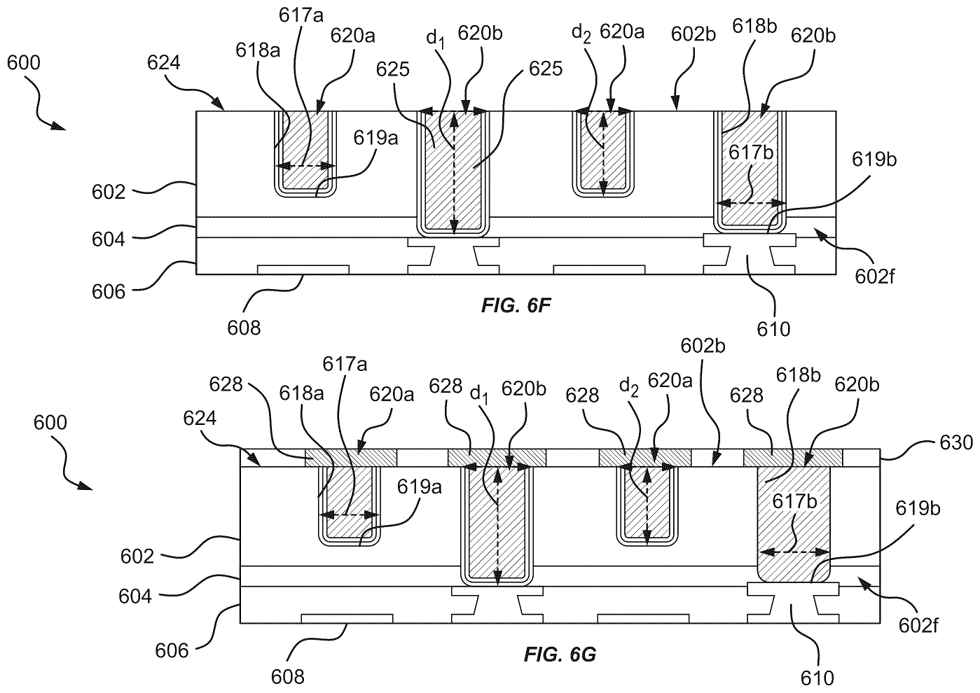

FIG. 5 illustrates a method 500 for forming at least one dummy feature through a semiconductor die according to one or more embodiments. FIGS. 6A-6G illustrate a cross-sectional view of a semiconductor die during formation of at least one dummy feature according to one or more embodiments.

At operation 505 and as illustrated in FIG. 6A, a semiconductor die 600 is provided. The semiconductor die 600 includes a substrate 602; a device layer 604 formed at the contact level, and interconnect layers 606. The device layer 604 and the interconnect layers 606 may be formed on a frontside 602f of the substrate 602. The substrate 602 may comprise the same material as substrate 202 of FIGS. 2A-2G. The interconnect layers 606 may be formed over the device layer 604. The interconnect layers 606 may include a combination of dielectric and metal layers. The interconnect layers 606 may also include conductive features 610, such as contacts, or interconnects that are formed through the interconnect layer 606. Metal pads 608 may be disposed over the interconnect layers 606. The metal pads 608 may comprise a conductive material such as copper. The metal pads 608 may be formed from a same conductive material or a different conductive material than the conductive features 610. Each conductive feature 610 may include a metal pad 608 formed thereon. In one or more embodiments, during fabrication of the conductive features 610 on the frontside 602f, dummy trenches 615, such as trenches, may be etched through a portion of the frontside 602f of the substrate 602. The dummy trenches 615 extend to a dummy depth 613 measured from the interconnect layers 606. The dummy trenches 615 are aligned with all or some of the conductive features 610. As will be described in more detail below the dummy trenches 615 are partially etched features that will be fully etched through the substrate 602 and used to house working TSVs in subsequent steps. The dummy trenches 615 extend to the dummy depth 613 ranging between 100 nm and 2 μm measured from the frontside 602f of the substrate 602. Stated otherwise the dummy trenches 615 extend through a portion of the substrate 602. In one or more embodiments, the dummy depth 613 is configured to be equal to the difference of the substrate thickness 603 and the depth of to be formed dummy feature(s). This will be explained in more detail below.

At operations 510-515, and as illustrated in FIG. 6B, a photoresist layer 612 is deposited and then patterned. The photoresist layer 612 is deposited on a backside 602b of the substrate 602. The photoresist layer 612 may comprise the same material and be formed in the same manner as the photoresist layer 212 in FIG. 2B. The photoresist layer 612 may be patterned to include patterned features 612a and patterned features 612b that expose portions of the backside 602b of the substrate 602. The patterned features 612a have a critical dimension 614 that is equal to the critical dimension 214 of FIG. 2B. The patterned features 612b have a critical dimension 616 that is equal to the critical dimension 216 of FIG. 2B. The patterned features 612a are positioned over metal pads 608 formed over the interconnect layers 606. The patterned features 612b are positioned over and are etched to include (i.e., form one continuous feature with) the dummy trenches 615. As will be described in more detail below, the patterned features 612a are sized to expose portions of the substrate 202 in which dummy features are to be formed. The patterned features 612b are patterned so that they are positioned above the dummy trenches 615 and that the critical dimension 616 is equal to the width of the dummy trenches 615.

At operation 520, and illustrated in FIG. features 620a and features 620b are etched into the portions of the substrate 602 exposed by the photoresist layer 612. The features 620a are etched into the portions of the substrate 602 exposed by the patterned features 612a. As noted above, dummy features are used to dissipate heat from the semiconductor die 600 and only extend through a portion of the substrate thickness 603 from the backside 602b. The features 620a each have a sidewall surface 618a, a bottom surface 619a, a width (critical dimension) 617a, and a depth d1 that extends from the backside 602b to the bottom surface 619a.

On the other hand, working TSVs extend from the backside 602b to the conductive features 610. Thus, the portions of the substrate 602 exposed by the patterned features 620b are etched until the dummy trenches 615 are reached, forming features 620b. Stated otherwise, the features 620b are formed by etching the remaining (unetched portions) of the substrate 602 that are exposed by the patterned features 612a. Therefore, the features 620a are configured to house dummy features and the features 620b are configured to house working TSVs. Because the dummy trenches 615 have the dummy depth 613, a single etching process can etch the exposed regions on the backside 602b of the substrate to the same depth, forming the features 620a and 620b in a single etching step. The etching of the features 620b will intersect with the dummy trenches 615, forming features 620b that extend throughout the entire substrate 602. Therefore, the features 620a each have sidewall surfaces 618a, a bottom surface 619a, a width (critical dimension) 617a, and a depth d2 that extends from the backside 602b to the interconnect layers 606. In one or more embodiments, the process of forming the features 620a and features 620b may be performed using a timed etching process.

At operation 525, the features 620a and the features 620b are filled, forming dummy features 626a and working TSVs 626b (FIGS. 6D-6F). Operation 525 may include operations 530-540.

At operation 530, as illustrated in FIG. 6D, a barrier layer 621 and a seed layer 622 are deposited in the features 620a and the features 620b. The barrier layer 621 and the seed layer 622 may be deposited in the same manner and comprise the same material as the barrier layer 221 and the seed layer 222 of FIG. 2D, respectively. The barrier layer 621 is deposited prior to the seed layer 622. The barrier layer 621 is deposited over the field region 624 (i.e., the unetched regions) of the backside 604b of the substrate 602 and line the sidewall surfaces 618a and bottom surface 619a of the features 620a and the sidewalls 618b and bottom surface 619b of the features 620b.

At operation 535, as illustrated in FIG. 6E a metal fill material 625 is formed over the substrate 602. The metal fill material 625 fills the remaining exposed portions of the features 620a and the features 620b and covers the field region of the substrate 602. Stated differently, the metal fill material 625 covers the seed layer 622. The metal fill material 625 may be formed in the same manner and comprise the same material as the metal fill material 225 of FIG. 2E.

At operation 540, as illustrated in FIG. 6F, the features 620a and the features 620b are planarized using a chemical mechanical polishing (CMP) process. The CMP process removes the metal fill material 625, the seed layer 622, and the barrier layer 621 from the field region 624 of the substrate 602, forming dummy features 626a in the features 620a and working TSVs 626b in the features 620b.

At operation 545, as illustrated in FIG. 6G metal pads 628 are formed over the dummy features 626a and the working TSVs 626b. The metal pads 628 may comprise the same material as the metal fill material 625, such as copper. The metal pads 628 may be formed using a patterned mask layer 630 in the same manner and comprise the same materials as the metal pads 228 (and the patterned mask layer 230) of FIG. 2G. In one or more examples, if only dummy features 626a are formed, operation 545 is optional.

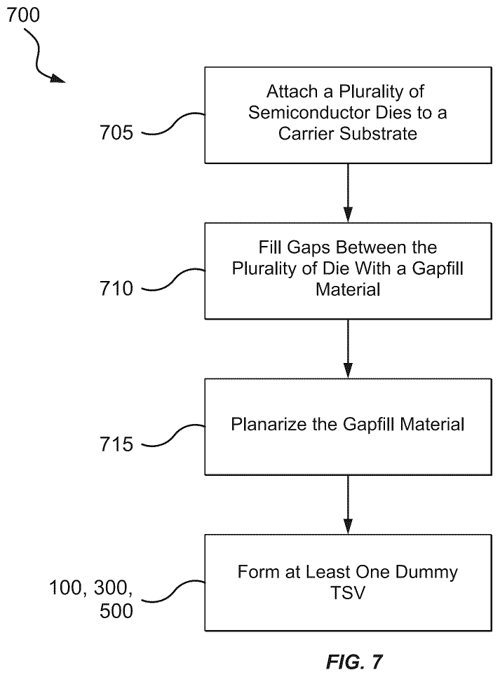

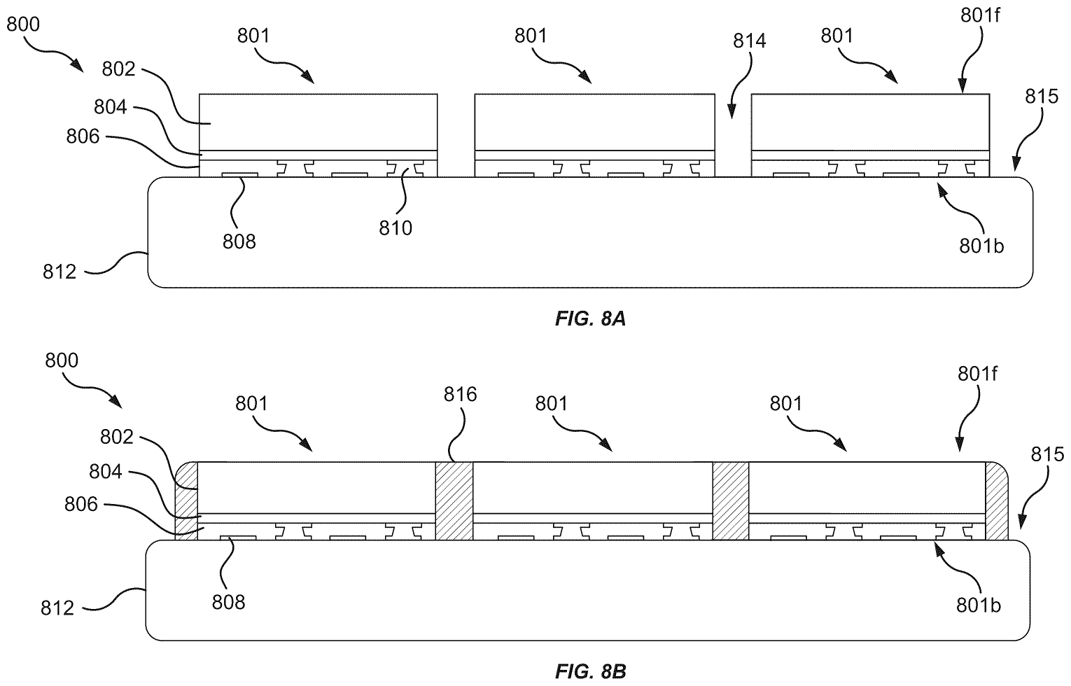

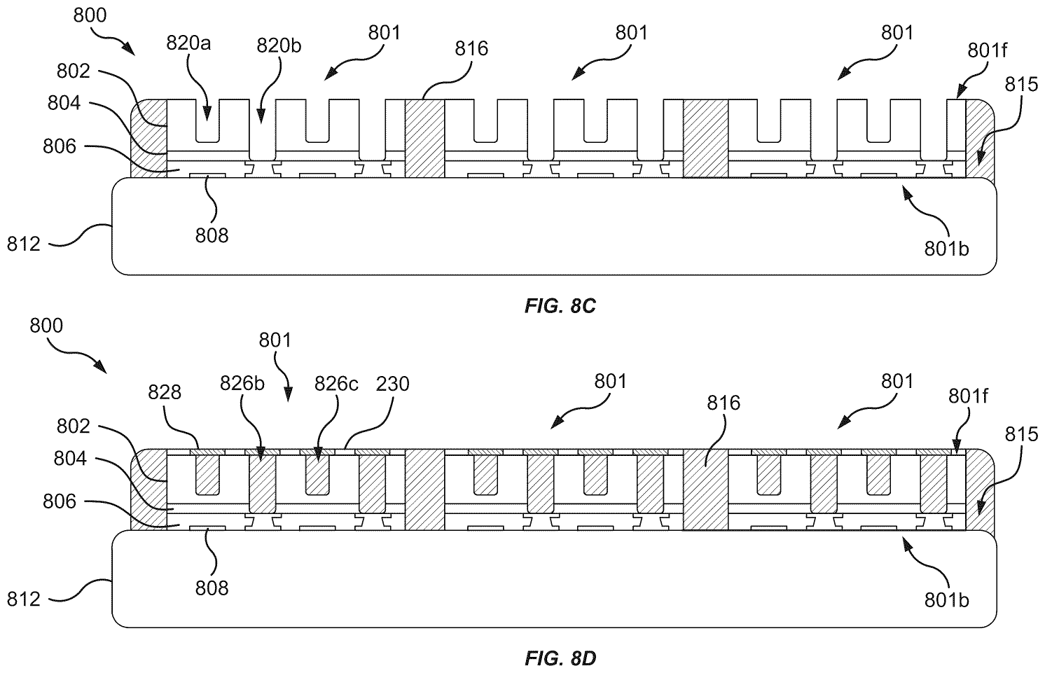

FIG. 7 illustrates a method 700 for a semiconductor device assembly including at least one TSV using die-to-wafer (D2W) bonding according to one or more embodiments. FIGS. 8A-8D illustrate a cross-sectional view of a semiconductor device during formation a semiconductor device assembly including at least one TSV using die-to-wafer (D2W) bonding according to one or more embodiments.

At operation 705 a plurality of semiconductor dies 801 are attached to a carrier substrate 812. A frontside 801b of the semiconductor dies 801 are attached to the carrier substrate 812. Each semiconductor die 801 includes a substrate 802, a device layer 804, and interconnect layers 806. The substrate 802 may correspond to substrates 202, 402, or 602 described in FIGS. 2A, 4A, and 6A, respectively. The device layer 804 may correspond to device layer 204, 404, or 604 described in FIGS. 2A, 4A, and 6A, respectively. The interconnect layers 806 may correspond to interconnect layers 206, 406, or 606 described in FIGS. 2A, 4A, and 6A, respectively. In one or more embodiments, each of the semiconductor dies 801 are attached to the carrier substrate 812 after they are diced. Therefore, there are gaps 814 formed between each of the semiconductor dies 801 and regions 815 formed between semiconductor dies 801 and a periphery of the carrier substrate 812. Each of the semiconductor dies 801 may be semiconductor die 200 of FIG. 2A, semiconductor die 400 of FIG. 4A, or semiconductor die 600. As shown in FIG. 8A, each of the semiconductor dies 801 are semiconductor die 200.

At operation 710, as illustrated in FIG. 8B, the gaps 814 and regions 815 are filled with a gapfill material 816 and are planarized using a CMP process. In one or more embodiments, the gapfill material 816 includes, but is not limited to, silicon nitride (SiN), silicon carbon nitride (SiCN), silicon oxygen nitride (SiON), silicon oxide (SiO), or the like. As shown in FIG. 8B, the gapfill material is planarized using a CMP process such that the gapfill material 816 has a thickness equal to the height of the semiconductor dies 801.

As illustrated in FIGS. 8C-8D, after operation 710 at least one dummy feature 826a is formed in each of the semiconductor dies 801 using one of methods 100, 300, and 500. For example, as illustrated in FIGS. 8C-8D, dummy features 826a and working TSVs 826b may be formed using method 100 of FIG. 1. For example, features 820a may be formed (FIG. 8C) and filled to form dummy features 826a (FIG. 8D). Features 820b may be formed (FIG. 8C) and filled to form working TSVs 826b (FIG. 8D). In some embodiments, at least one dummy feature 826a is formed in each of the semiconductor dies 801. In one embodiment, a same or different quantity of dummy features 826a are formed in each of the semiconductor dies 801. In another embodiment, a same or different quantity of working TSVs 826b are formed in each of the semiconductor dies 801. In some embodiments, some of the semiconductor dies 801 may not include a working TSV 826b. After forming the dummy features 826a and the working TSVs 826b, metal pads 828 are formed over each of the TSVs using patterned mask layer 830. The metal pads 828 and the patterned mask layer 830 may be formed of the same material and be formed in the same manner as metal pads 228 and patterned masking layer 230, respectively. As noted above if only dummy features 826a are formed, metal pads 828 are optional.

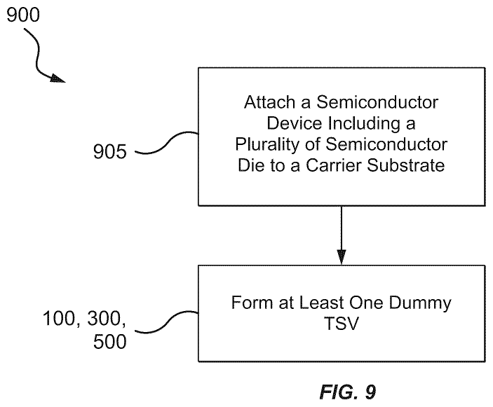

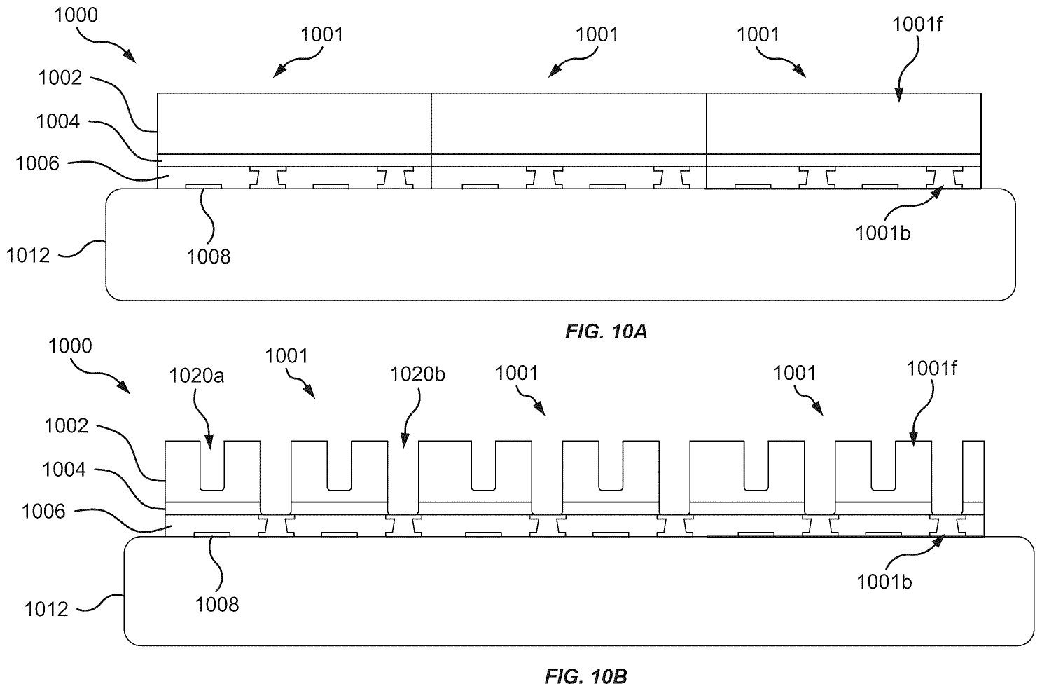

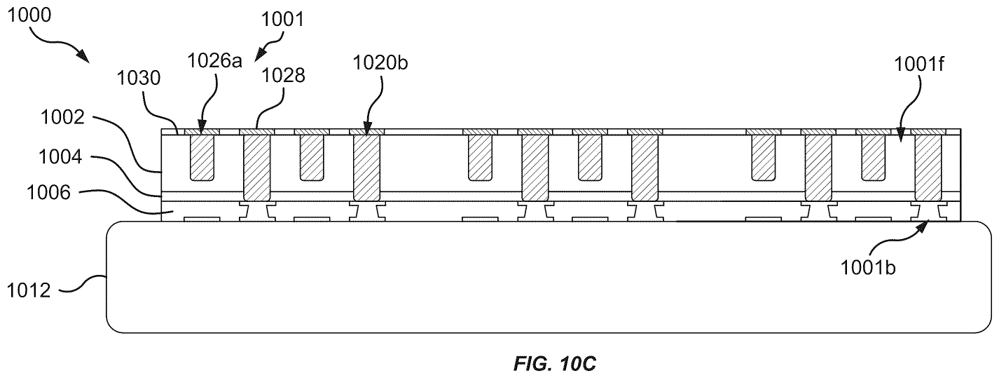

FIG. 9 illustrates a method 900 for a semiconductor device assembly including at least one TSV using wafer-to-wafer (W2W) bonding according to one or more embodiments. FIGS. 10A-10C illustrate a cross-sectional view of a semiconductor device during formation a semiconductor device assembly including at least one TSV using wafer-to-wafer (W2W) bonding according to one or more embodiments.

At operation 905 a semiconductor device 1000 including a plurality of semiconductor dies 1001 are attached to a carrier substrate 1012. The semiconductor dies 1001 are each bonded on a substrate 1002. A frontside 1001b of each semiconductor die 1001 is attached to the carrier substrate 1012. Each semiconductor die 1001 includes the substrate 1002, a device layer 1004, and interconnect layers 1006. The substrate 1002 may correspond to substrates 202, 402, or 602 described in FIGS. 2A, 4A, and 6A, respectively. The device layer 1004 may correspond to device layer 204, 404, or 604 described in FIGS. 2A, 4A, and 6A, respectively. The interconnect layers 1006 may correspond to interconnect layers 206, 406, or 606 described in FIGS. 2A, 4A, and 6A, respectively. Each of the semiconductor dies 1001 may be semiconductor die 200 of FIG. 2A, semiconductor die 400 of FIG. 4A, or semiconductor die 600. As shown in FIG. 8A, each of the semiconductor dies 801 are semiconductor die 200.

As illustrated in FIGS. 10B-10C, after operation 905 at least one dummy feature 1026a is formed in each of the semiconductor dies 1001 using one of methods 100, 300, and 500. For example, as illustrated in FIGS. 10B-10C, dummy features 1026a and working TSVs 1026b may be formed using method 100 of FIG. 1. For example, features 1020a may be formed (FIG. 10B) and filled to form dummy features 1026a (FIG. 10C). Features 1020b may be formed (FIG. 10B) and filled to form working TSVs 1026b (FIG. 10C). In some embodiments, at least one dummy feature 1026a is formed in each of the semiconductor dies 1001. In one embodiment, a same or different quantity of dummy features 1026a are formed in each of the semiconductor dies 1001. In another embodiment, a same or different quantity of working TSVs 1026b are formed in each of the semiconductor dies 1001. In some embodiments, some of the semiconductor dies 801 may not include a working TSV 1026b. After forming the dummy features 1026a and the working TSVs 1026b, metal pads 1028 are formed over each of the TSVs using patterned mask layer 1030. The metal pads 1028 may be formed of the same material and be formed in the same manner as metal pads 228. The patterned mask layer 1030 may be formed of the same material and be formed in the same manner as patterned masking layer 230, respectively.

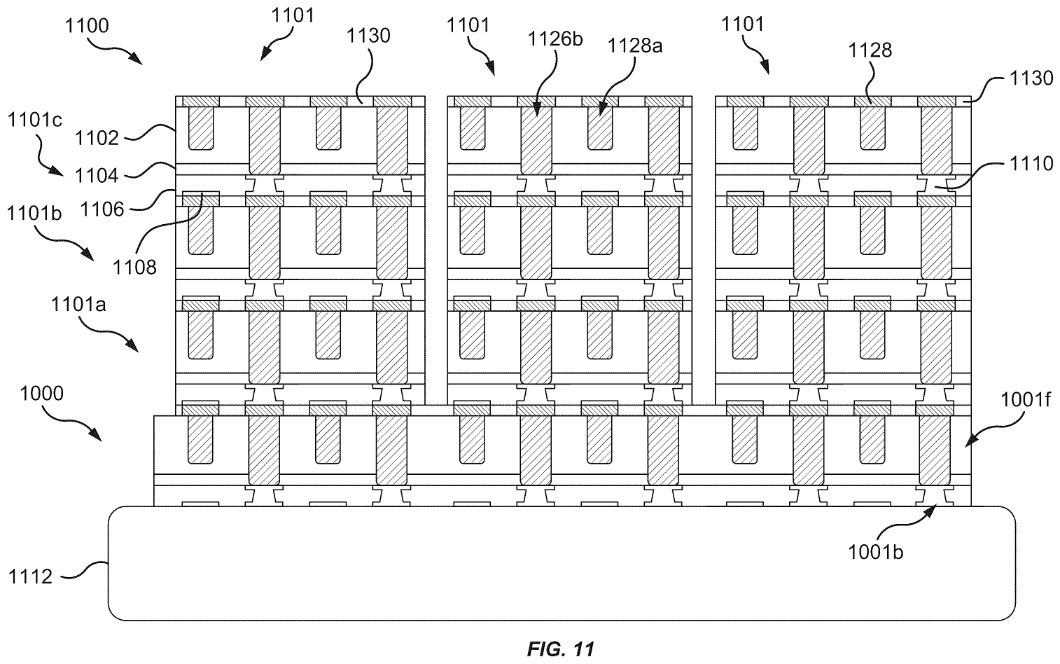

FIG. 11 illustrates a cross-sectional view of a stacked semiconductor assembly 1100 including at least one dummy feature according to one or more embodiments. As illustrated in FIG. 11, a plurality of semiconductor dies 1101 may be stacked over a semiconductor device 1000 attached to a substrate 1112 using W2W bonding (FIGS. 10A-10C). Each semiconductor die 1101 includes a substrate 1102, a device layer 1104, and interconnect layers 1106. The substrate 1102 may correspond to substrates 202, 402, or 602 described in FIGS. 2A, 4A, and 6A, respectively. The device layer 1104 may correspond to device layer 204, 404, or 604 described in FIGS. 2A, 4A, and 6A, respectively. The interconnect layers 1106 may correspond to interconnect layers 206, 406, or 606 described in FIGS. 2A, 4A, and 6A, respectively. As shown in FIG. 11 different levels of semiconductor dies 1101 may be stacked over the semiconductor device 1000 after dicing. For example, a first level 1101a of semiconductor dies 1101 may be stacked over the semiconductor device 1000, a second level 1101b of semiconductor dies 1101 may be stacked over the first level 1101a, and a third level 1101c of semiconductor dies 1101 may be stacked over the second level 1101b. Although each layer of semiconductor dies includes three dies each layer of semiconductor dies may include any suitable quantity of semiconductor dies. Furthermore, each layer of semiconductor dies may include a same or different quantity of semiconductor dies.

Although, as illustrated in FIG. 11, although, as illustrated in FIG. 11, the stacked semiconductor assembly 1100 includes semiconductor dies 1101 formed over a semiconductor device 1000 (FIGS. 10A-10C) formed using W2W bonding, the semiconductor dies 1101 may be formed over a semiconductor device assembly 800 (FIGS. 8A-8D) formed using D2D bonding.

Each of semiconductor die 1101 may include dummy features 1126a and working TSVs 1126b. Each of the TSVs, include metal pads 1128 formed thereon using a patterned mask layer 1130. The metal pads 1128 and the patterned mask layer 1130 may be formed of the same material and be formed in the same manner as metal pads 228 and patterned masking layer 230, respectively. Each working TSV 1126b on each level may be aligned (i.e., coupled to) a working TSV on a previous level forming interconnects throughout the stacked semiconductor assembly 1100. For example, each working TSV 1126b on the first level 1101a is coupled to a corresponding working TSV 1026b. Each working TSV 1126b on the second level 1101b is coupled to a corresponding working TSV 1126b on the first level 1101a. Each working TSV 1126b on the third level 1101c is coupled to a corresponding working TSV 1126b on the second level 1101b. Although a working TSV 1126b is included in each semiconductor die 1101, a same or different quantity of working TSVs 1126b may be included in each semiconductor die 1101. In other embodiments, working TSVs 1126b may or may not be included in each semiconductor die 1101. Furthermore, although a dummy feature 1126a is included in each semiconductor die 1101, a same or different quantity of dummy features 1126a may be included in each semiconductor die 1101. Advantageously, because heat is transferred vertically through the stacked semiconductor assembly the dummy features 1126a on each level of the device will wick away heat as heat is transferred vertically.

What is claimed is:

1. A semiconductor die comprising:
a substrate having a frontside opposing a backside;
a device layer disposed over the frontside of the substrate;
interconnect layers formed over the device layer; and
at least one dummy feature, the at least one dummy feature extending from the backside of the substrate through a portion of the substrate, wherein the dummy feature comprises one or more metal layers.

2. The semiconductor die of claim 1, further comprising at least one metal pad disposed over a surface on the frontside of the substrate, wherein the at least one metal pad is aligned in a first direction with each of the at least one dummy features, and the first direction is parallel to the surface.

3. The semiconductor die of claim 1, further comprising at least one metal pad disposed over the backside of the substrate and over each of the at least one dummy features.

4. The semiconductor die of claim 1, further comprising at least one working TSV, wherein the at least one working TSV extends from the backside of the substrate to an interconnect feature disposed within the interconnect layers.

5. The semiconductor die of claim 4, wherein the at least one working TSV has a larger width than the at least one dummy feature.

6. A method comprising:
depositing a photoresist layer on a backside of a substrate, the substrate comprising a device layer disposed on a frontside of the substrate, and interconnect layers disposed over the device layer;
patterning the photoresist layer to form first patterned features that expose portions of the backside of the substrate, the first patterned features having a first critical dimension;
etching the portions of the backside of the substrate exposed by the first patterned features using a first etching process to form first features, the first features extending from the backside of the substrate through a portion of the substrate; and
filling the first features with a metal to form dummy features.

7. The method of claim 6, wherein filling the first features comprises:
depositing a barrier layer in the first features, the barrier layer lining sidewalls and a bottom surface of the first features;
depositing a seed layer over the barrier layer; and
filling the first features with a metal fill material; and
planarizing the first features using a CMP process.

8. The method of claim 6, further comprising patterning the photoresist layer to form second patterned features that expose portions of the backside of the substrate, the second patterned features are aligned with conductive features formed in the interconnect layers and have a second critical dimension different from the first critical dimension.

9. The method of claim 8, wherein the second critical dimension is greater than the first critical dimension.

10. The method of claim 8, further comprising etching second features through the portions of the backside of the substrate exposed by the second patterned features, the second features extending from the backside of the substrate to a corresponding conductive feature.

11. The method of claim 10, wherein the etching second features is performed etched during the first etching process or is performed using a second etching process performed after the first etching process and prior to filling the first features.

12. The method of claim 11, further comprising filling the second features with a metal to form working TSVs.

13. The method of claim 6, further comprising forming metal pads over the first features after filling the first features with a metal.

14. The method of claim 13, wherein forming the metal pads over the first features comprises:
forming a patterned mask layer over the backside of the substrate that exposes the first features; and
depositing a conductive material over the exposed first features.

15. The method of claim 6, wherein the substrate comprises second features that are aligned with a corresponding conductive feature and extend from the backside of the substrate to a corresponding conductive feature prior to the depositing of the photoresist layer on the backside of a substrate.

16. The method of claim 15, further comprising filling the second features to form working TSVs.

17. The method of claim 6, wherein the substrate comprises dummy trenches that are aligned with a corresponding conductive feature and extend from the backside of the substrate to a dummy depth measured from the frontside of the substrate.

18. The method of claim 17, wherein the dummy depth is equal to a thickness of the substrate and a depth of the first features.

19. The method of claim 18, further comprising:
patterning the photoresist layer to form second patterned features that expose portions of the backside of the substrate, the second patterned features are aligned with the dummy trenches and have a second critical dimension different from the first critical dimension;
etching the portions of the backside of the substrate between the dummy trenches and the backside of the substrate to form second features; and
filling the first features and the second features.

20. A stacked semiconductor assembly comprising:
a second level of semiconductor dies disposed above a first level of semiconductor dies, each of the semiconductor dies comprising:
a substrate having a frontside opposing a backside;
a device layer disposed over the frontside of the substrate;
interconnect layers formed over the device layer, the interconnect layers having interconnect features formed therein;
at least one dummy feature, the at least one dummy feature extending from the backside of the substrate through a portion of the substrate, wherein the dummy feature comprises a metal; and
at least one working TSV extending from the backside of the substrate to a corresponding interconnect feature, wherein each of the at least one working TSV of each of the semiconductor dies of second level of semiconductor dies is aligned with a corresponding working TSV of the at least one working TSV of each of the semiconductor dies of first level of semiconductor dies.
